(19) United States
(12) Patent Application Publication
(10) Pub. No.: US 2025/0275393 A1
(43) Pub. Date: Aug. 28, 2025

(54) DISPLAY DEVICE AND METHOD OF FABRICATING DISPLAY DEVICE

(71) Applicant: Samsung Display Co., LTD., Yongin-si (KR)

(72) Inventors: Je Won YOO, Yongin-si (KR); Dong Jo KIM, Yongin-si (KR); Hyun KIM, Yongin-si (KR); Seong Geun WON, Yongin-si (KR); So Young LEE, Yongin-si (KR); Seung Min LEE, Yongin-si (KR); Young Hoon LEE, Yongin-si (KR); Dan Bi CHOI, Yongin-si (KR); Souk June HWANG, Yongin-si (KR)

(73) Assignee: Samsung Display Co., LTD., Yongin-si (KR)

(21) Appl. No.: 18/952,342

(22) Filed: Nov. 19, 2024

(30) Foreign Application Priority Data
Feb. 23, 2024 (KR) 10-2024-0026583

(51) Int. Cl. H10K 59/131; H10K 59/12; H10K 102/00

(52) U.S. Cl. CPC H10K 59/131; H10K 59/1201; H10K 2102/311

(57) ABSTRACT

A display device includes a first substrate including a first sub-substrate in line with a main area; and a second substrate including a second sub-substrate in line with a pad area and spaced apart from the first sub-substrate with the bending area between the first sub-substrate and the second sub-substrate, the first sub-substrate includes an edge portion at an edge surrounding the first sub-substrate in plan view, the edge portion includes a first side surface facing the bending area, a second side surface spaced apart from the first side surface, and a first corner between the first side surface and the second side surface, and the first sub-substrate has a different cross-sectional shapes at the first side surface, the second side surface and the first corner in cross-section.

### CROSS-REFERENCE TO RELATED APPLICATION(S)

This application claims priority to and benefits of Korean Patent Application No. 10-2024-0026583 under 35 U.S.C. § 119, filed on Feb. 23, 2024, in the Korean Intellectual Property Office, the entire contents of which are incorporated herein by reference.

### BACKGROUND

### 1. Technical Field

The disclosure relates to a display device, and a method of fabricating the display device.

### 2. Description of the Related Art

As the information-oriented society evolves, various demands for display devices are ever increasing. As the information-oriented society evolves, various demands for display devices are ever increasing.

A display device may include a display area where images are displayed, and a non-display area around the display area, for example. Recently, the width of the non-display area is ever decreasing in order for viewers to get more immersed in the contents displayed on the display area and to increase the aesthetics of the display device.

In the process of fabricating a display device, the display device may be formed by cutting a mother substrate along the display cells formed thereon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a method of fabricating a display device that can increase the number of display cells included in a mother substrate by reducing the spacing between the display cells arranged (or disposed) in the mother substrate during the process of fabricating the display device.

It should be noted that objects of the disclosure are not limited to the above-mentioned objects. Other objects will be apparent to those skilled in the art from the following descriptions.

Various embodiments of the disclosure are included in the detailed description and the accompanying drawings.

In an embodiment, a display device may include a first substrate including a main area and a pad area; and a second substrate disposed on the main area and the pad area of the first substrate, the second substrate comprising a bending area disposed between the main area and the pad area, wherein the first substrate comprises a first sub-substrate in line with the main area; and a second sub-substrate in line with the pad area and spaced apart from the first sub-substrate with the bending area between the first sub-substrate and the second sub-substrate, wherein the first sub-substrate comprises an edge portion at an edge surrounding the first sub-substrate in plan view, wherein the edge portion of the first sub-substrate comprises a first side surface facing the bending area, a second side surface spaced apart from the first side surface, and a first corner disposed between the first side surface and the second side surface, and the first sub-substrate may have different cross-sectional shapes at the first side surface, the second side surface and the first corner in cross-section.

In an embodiment, the first sub-substrate may comprise a first surface facing the second substrate and a second surface opposed to the first surface, wherein the first sub-substrate may further comprise a first side surface connected to the first surface at the first corner, and a first inclination angle formed by the first surface and the first side surface may be an obtuse angle.

In an embodiment, an undercut may be formed between the first side surface and the second substrate toward an outside of the first sub-substrate.

In an embodiment, the first sub-substrate may further comprise a second side surface connecting the second surface and the first surface at the first corner, and wherein a second inclination angle formed by the second surface and the second side surface may be an obtuse angle.

In an embodiment, the first sub-substrate may further comprise a first bending side surface connected to the first surface at the first side surface, and a second bending side surface connecting the first bending side surface with the second surface, wherein a first bending inclination angle formed by the first surface and the first bending side surface may be an obtuse angle, and the first bending inclination angle and the first inclination angle may be different from each other.

In an embodiment, a second bending inclination angle formed by the second surface and the second bending side surface at the first side surface may be an obtuse angle, and wherein the second inclination angle and the second bending inclination angle may be different from each other.

In an embodiment, the first sub-substrate may further comprise a first edge surface connected to the first surface at the second side surface and a second edge surface connecting the first edge surface with the second surface, and wherein no undercut may be included between the second substrate and the first edge surface at the second side surface.

In an embodiment, a first edge inclination angle formed by the first edge surface and the second edge surface may be an obtuse angle.

In an embodiment, a second edge inclination angle formed by the second surface and the second edge surface at the second side surface may be an obtuse angle, and wherein the second inclination angle and the second edge inclination angle may be different from each other.

In an embodiment, a thickness of the first substrate may be greater than a thickness of the second substrate.

In an embodiment, the thickness of the first substrate may be equal to about 200 μm.

In an embodiment, the second sub-substrate may comprise an edge portion at an edge surrounding the second sub-substrate in plan view, wherein the edge portion of the second sub-substrate comprises a third side surface facing the bending area, a fourth side surface spaced apart from the first side surface, and a second corner disposed between the third side surface and the fourth side surface, and the second sub-substrate may have different cross-sectional shapes at the third side surface, the fourth side surface and the second corner in cross-section.

In an embodiment, the second sub-substrate may comprise a first surface facing the second substrate and a second surface opposed to the first surface, wherein the second sub-substrate further comprises a first side surface connected to the first surface at the second corner, and a second side surface connecting the second surface with the first side surface, and a first inclination angle formed by the first surface and the first side surface and a second inclination angle formed by the second surface and the second side surface may be obtuse angles.

In an embodiment, an undercut may be formed between the first side surface and the second substrate toward an outside of the second sub-substrate.

In an embodiment, the second sub-substrate may further comprise a first edge surface connected to the first surface at the fourth side surface and a second edge surface connecting the first edge surface with the second surface, and wherein no undercut is included between the second substrate and the first edge surface at the fourth side surface.

In an embodiment, the second sub-substrate may further comprise a first bending side surface connected to the first surface at the third side surface, and a second bending side surface connecting the first bending side surface with the second surface, wherein a first bending inclination angle formed by the first surface and the first bending side surface and a second bending inclination angle formed by the second surface and the second bending side surface may be obtuse angles, wherein the first bending inclination angle and the first inclination angle may be different from each other, and the second bending inclination angle and the second inclination angle may be different from each other.

In an embodiment, a method of fabricating a display device, the method may include forming a mother substrate comprising a first mother substrate and a second mother substrate disposed on a first surface of the first mother substrate, and forming a plurality of display cells on the mother substrate; etching a portion of the first mother substrate disposed at a bending pattern portion by spraying an etchant or forming a groove using a blade on a second surface of the first mother substrate disposed on an opposite side of the first surface; forming a cell-cut line along edges of the plurality of display cells by irradiating a laser on the second surface; and forming a first substrate by spraying an etchant on the second surface without a mask to cut the first mother substrate and simultaneously removing the first mother substrate at the bending pattern portion, wherein a part of the cell-cut line intersects the bending pattern portion.

In an embodiment, the first mother substrate at an intersection of the cell-cut line and the bending pattern portion may have a first side surface and a second side surface connected to the first side surface toward the cell-cut line and the bending pattern portion, wherein the first side surface may be connected to the first surface of the first mother substrate, and the second side surface may be connected to the second surface of the first mother substrate, and an undercut may be formed between the first side surface and the second mother substrate toward an outside of the first substrate.

In an embodiment, a first inclination angle formed by the first surface of the first mother substrate and the first side surface may be an obtuse angle.

In an embodiment, a second inclination angle formed by the second surface of the first mother substrate and the first side surface may be an obtuse angle.

In an embodiment, an electronic device includes a display device comprising a first substrate comprising a main area and a pad area; and a second substrate disposed on the main area and the pad area of the first substrate, the second substrate comprising a bending area disposed between the main area and the pad area, wherein the first substrate comprises: a first sub-substrate in line with the main area; and a second sub-substrate in line with the pad area and spaced apart from the first sub-substrate with the bending area between the first sub-substrate and the second sub-substrate, the first sub-substrate comprises an edge portion at an edge surrounding the first sub-substrate in plan view, the edge portion of the first sub-substrate comprises: a first side surface facing the bending area, a second side surface spaced apart from the first side surface, and a first corner disposed between the first side surface and the second side surface, and the first sub-substrate has different cross-sectional shapes at the first side surface, the second side surface and the first corner in cross-section.

According to an embodiment, a cell-cut line surrounding a plurality of display cells may intersect a bending pattern portion in a bending area of each display device during a process of fabricating display devices. Therefore, in the display device according to the embodiment, separating a plurality of display cells and removing the first substrate at the bending pattern portion can be performed in a single process during the process of fabricating the display devices.

Accordingly, in the display device according to the embodiment, the spacing between the display cells can be minimized, and accordingly the number of the display cells in the mother substrate can be increased during the process of fabricating display devices. It is possible to provide convenience and ease of fabrication.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view showing a display device according to an embodiment.

FIG. 2 is a schematic plan view showing a display panel and driver ICs according to the embodiment.

FIG. 3 is a schematic cross-sectional view of the display device of FIG. 2.

FIG. 4 is a schematic cross-sectional view of the display device of FIG. 3 in case that the display panel is bent.

FIG. 5 is a schematic plan view of the first substrate and the second substrate in FIG. 2.

FIG. 6 is a schematic cross-sectional view taken along line Y1-Y1′ of FIG. 5.

FIG. 7 is a schematic cross-sectional view taken along line Y3-Y3′ of FIG. 5.

FIG. 8 is a flowchart for illustrating a method of fabricating a display device according to an embodiment.

FIG. 9 is a schematic perspective view for illustrating step S100 of FIG. 8.

FIG. 10 is a schematic cross-sectional view taken along line X1-X1′in FIG. 9.

FIG. 11 is a schematic perspective view showing step S201 of step S200 in FIG. 8.

FIGS. 12 and 13 are schematic cross-sectional views taken along line Y5-Y5′ of FIG. 11.

FIG. 14 is a schematic perspective view showing step S202 of step S200 in FIG. 8.

FIG. 15 is a schematic cross-sectional view taken along line Y7-Y7′ of FIG. 14.

FIG. 16 is a schematic perspective view for illustrating step S300 of FIG. 8.

FIG. 17 is a schematic cross-sectional view, taken along line X3-X3′ in FIG. 16.

FIG. 18 is a schematic perspective view for illustrating step S400 of FIG. 8.

FIGS. 19 and 20 are schematic cross-sectional views, taken along line X5-X5′ of FIG. 18.

FIG. 21 is a schematic cross-sectional view, taken along line Y9-Y9′ of FIG. 18.

FIG. 22 is a schematic cross-sectional view, taken along line X7-X7′ of FIG. 18.

FIG. 23 is a schematic perspective view for illustrating step S500 of FIG. 8.

### DETAILED DESCRIPTION OF THE EMBODIMENTS

In the following description, for the purposes of explanation, numerous details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these details or with one or more equivalent arrangements. Here, various embodiments do not have to be exclusive nor limit the disclosure. For example, shapes, configurations, and characteristics of an embodiment may be used or implemented in an embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terminology used herein is for the purpose of describing embodiments and is not intended to be limiting.

As used herein, the singular forms, “a,” “an,” and “the” are intended to include the plural forms as well, unless the context clearly indicates otherwise.

Moreover, the terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

“About” or “approximately” as used herein is inclusive of the stated value and means within an acceptable range of deviation for the value as determined by one of ordinary skill in the art, considering the measurement in question and the error associated with measurement of the quantity (for example, the limitations of the measurement system). For example, “about” can mean within one or more standard deviations, or within ±30%, 20%, 10% or 5% of the stated value.

As customary in the field, an embodiment is described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of an embodiment may be physically separated into two or more interacting and discrete blocks, units, and/or modules without departing from the scope of the disclosure. Further, the blocks, units, and/or modules of an embodiment may be physically combined into more complex blocks, units, and/or modules without departing from the scope of the disclosure.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described with reference to the accompanying drawings.

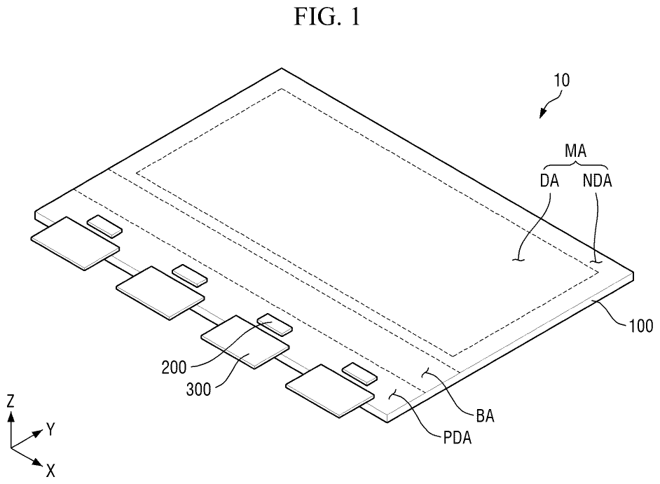

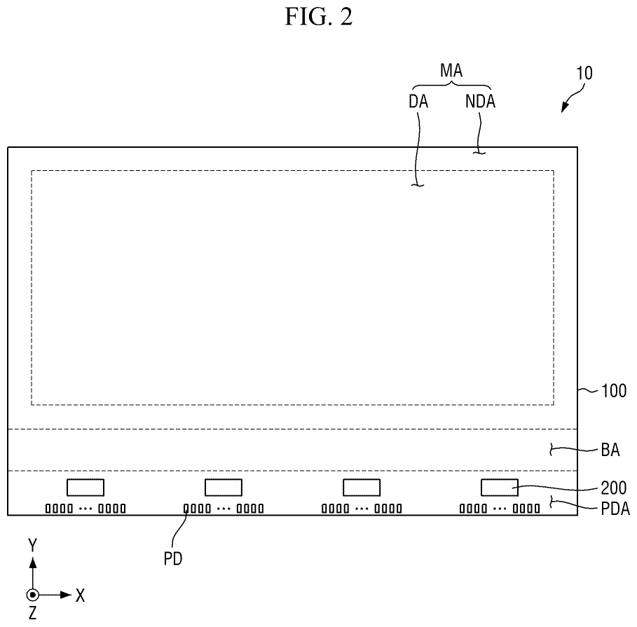

FIG. 1 is a schematic perspective view showing a display device according to an embodiment. FIG. 2 is a schematic plan view showing a display panel and driver ICs according to the embodiment.

Referring to FIGS. 1 and 2, a display device 10 according to an embodiment is for displaying moving images or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things device.

According to an embodiment, the display device 10 may be a light-emitting display device such as an organic light-emitting display device using organic light-emitting diodes, a quantum-dot light-emitting display device including quantum-dot light-emitting layer, an inorganic light-emitting display device including an inorganic semiconductor, and a micro-LED display device using micro or nano light-emitting diodes (micro LEDs or nano LEDs). In the following description, an organic light-emitting display device is described as an example of the display device 10. It is, however, to be understood that the disclosure is not limited thereto.

The display device 10 according to the embodiment may include a display panel 100, a driver integrated circuits (ICs) 200, and circuit boards 300.

The display panel 100 may be formed in a rectangular plane having longer sides in a first direction (x-axis direction) and shorter sides in a second direction (y-axis direction) intersecting the first direction (x-axis direction). Each of the corners where the longer side in the first direction (x-axis direction) meets the shorter side in the second direction (y-axis direction) may be formed at a right angle or may be rounded with a curvature. The shape of the display panel 100 in plan view is not limited to a quadrangular shape, but may be formed in a different polygonal shape, a circular shape, or an elliptical shape.

In the drawings, the first direction (x-axis direction) and the second direction (y-axis direction) intersect each other as the horizontal directions. For example, the first direction (x-axis direction) and the second direction (y-axis direction) may be orthogonal to each other. The third direction (z-axis direction) may intersect the first direction (x-axis direction) and the second direction (y-axis direction), and may be, for example, a vertical direction orthogonal to them. Herein, the side indicated by the arrow of each of the first to third directions (x-axis direction, y-axis direction and z-axis direction) may be referred to as a first side, while the opposite side may be referred to as a second side.

The display panel 100 may be formed flat, but the disclosure is not limited thereto. For example, the display panel 100 may be formed at left and right ends, and may include a curved portion having a constant curvature or a varying curvature. The display panel 100 may be flexible so that it can be curved, bent, folded or rolled.

The display panel 100 may include a main area MA, a bending area BA, and a pad area PDA. The main area MA may include a display area DA where images are displayed, and a non-display area NDA around the display area DA.

The display area DA may occupy most of the area of the display panel 100. The display area DA may be disposed at the center of the display panel 100. In the display area DA, pixels each including emission areas may be disposed to display images.

The non-display area NDA may be disposed adjacent to the display area DA. The non-display area NDA may be located (or disposed) on the outer side of the display area DA. The non-display area NDA may surround or may be adjacent to the display area DA. The non-display area NDA may be defined as the border of the display panel 100.

The bending area BA may be located between the display area DA and the pad area PDA in the second direction (y-axis direction). The bending area BA may be extended in the first direction (x-axis direction). The bending area BA may be bent such that it is located under (or below) the display panel 100. In case that the bending area BA is bent and located under the display panel 100, the driver ICs 200 and the circuit boards 300 may be located under the display panel 100.

The pad area PDA may be the lower edge area of the display panel 100. In the pad area PDA, display pads PD may be disposed to be connected to the circuit boards 300. The display pads PD may be disposed at one edge or an edge of the display panel 100. For example, the display pads PD may be disposed at the lower edge of the display panel 100.

The driver ICs 200 may be disposed in the pad area PDA. The driver ICs 200 may be disposed between the display pads PD and the display area DA in the non-display area NDA. The driver ICs 200 may be attached to the non-display area NDA of the display panel 100 by a chip on glass (COG) technique. By way of example, the driver ICs 200 may be attached to the circuit boards 300, respectively, by a chip on plastic (COP) technique.

The circuit boards 300 may be disposed on the display pads PD disposed at one edge or an edge of the display panel 100. The circuit boards 300 may be attached to the display pads PD using a conductive adhesive member such as an anisotropic conductive film and an anisotropic conductive adhesive. The circuit boards 300 may be electrically connected to signal lines of the display panel 100. The circuit boards 300 may be flexible printed circuit boards, flexible films such as chip on films.

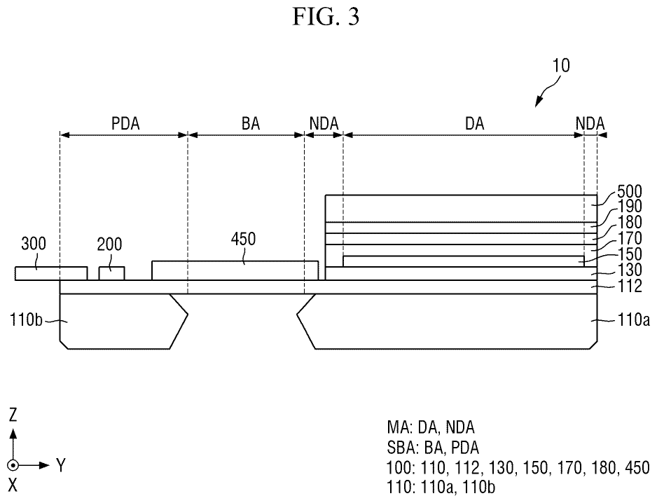

FIG. 3 is a schematic cross-sectional view of the display device 10 of FIG. 2.

Referring to FIG. 3, the display device 10 according to the embodiment may include the display panel 100, a polarizing film 190 and a cover window 500. The display panel 100 may include a first substrate 110, a second substrate 112, a thin-film transistor layer 130, a display element layer 150, a thin-film encapsulation layer 170, a touch sensor layer 180, and the bending protection layer 450.

The first substrate 110 may have a rigid material that can transmit light. For example, the first substrate 110 may be a glass or plastic substrate. The first substrate 110 may be formed of ultra thin glass (UTG) having a thickness of about 200 μm or less. According to the embodiment, the first substrate 110 may support the second substrate 112.

According to the embodiment, the first substrate 110 may include a first sub-substrate 110a and a second sub-substrate 110b. In cross section, the first sub-substrate 110a and the second sub-substrate 110b may be spaced apart from each other in the second direction (y-axis direction). The first sub-substrate 110a may overlap the main area MA, and the second sub-substrate 110b may overlap the pad area PDA.

According to the embodiment, a portion of the bending area BA of the first substrate 110 may be removed via an etching process during the process of fabricating the display device 10. For example, the first sub-substrate 110a and the second sub-substrate 110b may be formed integrally and may be spaced apart each other via the etching process described above. The fabrication process will be described later. Although a portion of the first sub-substrate 110a and a portion of the second sub-substrate 110b overlap the bending area BA in the drawings, but the disclosure is not limited thereto.

The second substrate 112 may be located on the first substrate 110. The second substrate 112 may be located such that it overlaps the main area MA and the subsidiary area SBA. The second substrate 112 may have a thickness of about 20 μm. The second substrate 112 may be made of a polymer resin having a flexible material. For example, the second substrate 112 may be formed of an organic material such as an acryl resin, an epoxy resin, a phenolic resin, a polyamide resin and a polyimide resin.

The thin-film transistor layer 130 may be disposed on the second substrate 112. The thin-film transistor layer 130 may be located such that it overlaps the display area DA and the non-display area NDA of the main area MA. The thin-film transistor layer 130 may include thin-film transistors and lines.

The display element layer 150 may be disposed on the thin-film transistor layer 130. The display element layer 150 may be disposed such that it overlaps the display area DA of the main area MA. The display element layer 150 may be a layer that displays images.

The thin-film encapsulation layer 170 may be disposed on the display element layer 150. The thin-film encapsulation layer 170 may be located such that it overlaps the display area DA and the non-display area NDA of the main area MA. The thin-film encapsulation layer 170 can prevent oxygen or moisture from permeating into the display element layer 150. The thin-film encapsulation layer 170 may include at least one organic film and an organic film, and the organic film of the thin-film encapsulation layer 170 can protect the display element layer 150 from foreign substances such as dust.

The touch sensor layer 180 may be disposed on the display element layer 150. The touch sensor layer 180 may be located such that it overlaps the display area DA and the non-display area NDA of the main area MA. The touch sensor layer 180 may include sensor electrodes and may detect a user's touch using the sensor electrodes.

The polarizing film 190 may be positioned on the touch sensor layer 180. The polarizing film 190 may be located such that it overlaps the display area DA and the non-display area NDA of the main area MA. The polarizing film 190 can reduce reflection of external light.

The cover window 500 may be disposed on the polarizing film 190. The cover window 500 may be located such that it overlaps the display area DA and the non-display area NDA of the main area MA. The cover window 500 may be attached onto the polarizing film 190 by a transparent adhesive member such as an optically clear adhesive (OCA) film.

The bending protection layer 450 may be located on the second substrate 112. The bending protection layer 450 may be located such that it overlaps the bending area BA. The bending protection layer 450 can protect the display panel 100 from bending stress in case that the display panel 100 overlapping the bending area BA is bent.

The bending protection layer 450 may include a synthetic resin. For example, the bending protection layer 450 may include at least one of: acrylonitrile butadiene styrene copolymer (ABS), urethane acrylate (UA), polyurethane (PU), polyethylene (PE), ethylene vinyl acetate (EVA) and polyvinyl chloride (PVC).

The driver ICs 200 and the circuit boards 300 may be located on the second substrate 112. In cross-section, the driver ICs 200 and the circuit boards 300 may be located such that they overlap the pad area PDA. In cross-section, the driver ICs 200 may be positioned between the bending protection layer 450 and the circuit boards 300, and the driver ICs 200 may be spaced apart from the bending protection layer 450 and the circuit boards 300. One side or a side of each of the circuit boards 300 may be in contact with the second substrate 112.

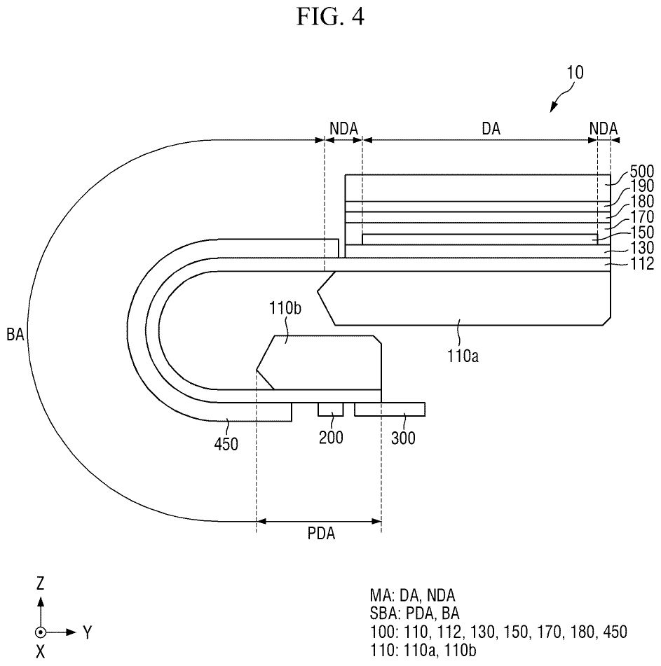

FIG. 4 is a schematic cross-sectional view of the display device 10 in case that the display panel 100 in FIG. 3 is bent.

Referring to FIG. 4, a portion of the display panel 100 that overlaps the bending area BA may be bent. In case that the portion of the display panel 100 overlapping the bending area BA is bent, the pad area PDA of the display device 10 may overlap the main area MA in the third direction (z-axis direction). In case that the portion of the display panel 100 that overlaps the bending area BA is bent, the first sub-substrate 110a and the second sub-substrate 110b may overlap each other in the third direction (z-axis direction).

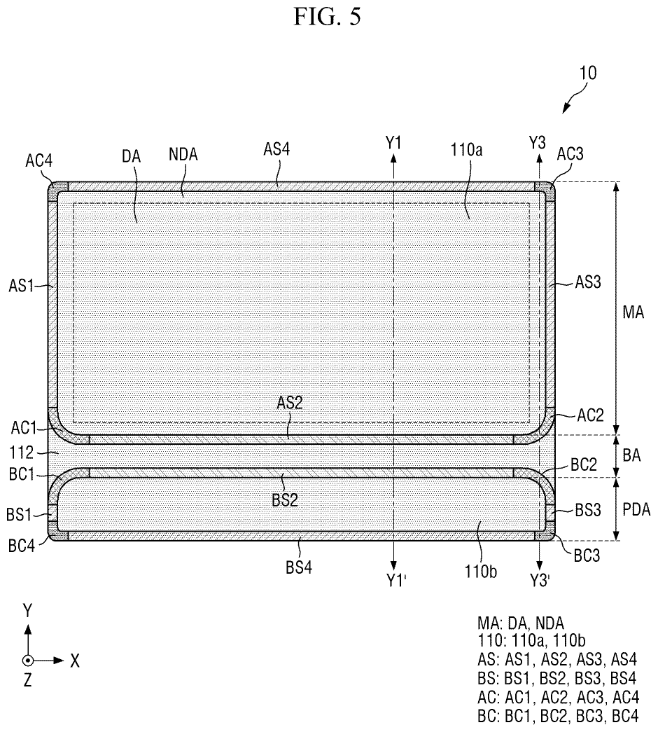

FIG. 5 is a schematic plan view of the first substrate 110 and the second substrate 112 in FIG. 2.

Referring to FIG. 5, according to the embodiment, the first substrate 110 may include a first sub-substrate 110a and a second sub-substrate 110b in plan view. The first sub-substrate 110a and the second sub-substrate 110b may be spaced apart from each other in the second direction (y-axis direction). In plan view, the second substrate 112 according to the embodiment may entirely cover the first substrate 110. In other words, the second substrate 112 according to the embodiment may entirely cover the first sub-substrate 110a and the second sub-substrate 110b in plan view, and the first sub-substrate 110a and the second sub-substrate 110b spaced apart from each other in the second direction (y-axis direction) may be connected by the second substrate 112.

The first substrate 110 according to the embodiment may include edge portions EG in plan view. The edge portions EG may refer to the portions surrounding the borders of the first sub-substrate 110a and the second sub-substrate 110b. In other words, the edge portions EG may refer to the edges of the first substrate 110. For example, the edge portions EG of the first sub-substrate 110a may be located such that they overlap the non-display area NDA included in the main area MA, and may surround the display area DA included in the main area MA. The edge portions EG of the second sub-substrate 110b may be located such that they overlap the pad area PDA. Although a part of the edge portions EG included the first sub-substrate 110a and a part of the edge portions EG included in the second sub-substrate 110b overlap the bending area BA in the drawings, the disclosure is not limited thereto.

The first sub-substrate 110a may include side surfaces AS and corners AC at the edge portions EG in plan view. The side surfaces AS included in the first sub-substrate 110a may include a first side surface AS1, a second side surface AS2, a third side surface AS3, and a fourth side surface AS4. The first side surface AS1 may be located on the left side of the display area DA, the second side surface AS2 may be located on the lower side of the display area DA, the third side surface AS3 may be located on the right side of the display area DA, and the fourth side surface AS4 may be located on the upper side of the display area DA.

The corners AC included in the first sub-substrate 110a may include a first corner AC1, a second corner AC2, a third corner AC3, and a fourth corner AC4. The first corner AC1 may be located between the first side surface AS1 and the second side surface AS2, and for example, may be in contact with the lower side of the first side surface AS1 and the left side of the second side surface AS2. The second corner AC2 may be located between the second side surface AS2 and the third side surface AS3, and for example, may be in contact with the right side of the second side surface AS2 and the lower side of the third side surface AS3. The third corner AC3 may be located between the third side surface AS3 and the fourth side surface AS4, and for example, may be in contact with the upper side of the third side surface AS3 and the right side of the fourth side surface AS4. The fourth corner AC4 may be located between the first side surface AS1 and the fourth side surface AS4, and for example, may be in contact with the upper side of the first side surface AS1 and the left side of the fourth side surface AS4.

The second sub-substrate 110b may include side surfaces BS and corners BC at the edge portions EG in plan view. The side surfaces BS included in the second sub-substrate 110b may include a first side surface BS1, a second side surface BS2, a third side surface BS3, and a fourth side surface BS4. The first side surface BS1 may be located at the left end of the pad area PDA, the second side surface BS2 may be located on the upper end of the pad area PDA, the third side surface BS3 may be located on the right end of the pad area PDA, and the fourth side surface BS4 may be located on the lower end of the pad area PDA.

The corners BC included in the second sub-substrate 110b may include a first corner BC1, a second corner BC2, a third corner BC3, and a fourth corner BC4. The first corner BC1 may be located between the first side surface BS1 and the second side surface BS2, and for example, may be in contact with the upper side of the first side surface BS1 and the left side of the second side surface BS2. The second corner BC2 may be located between the second side surface BS2 and the third side surface BS3, and for example, may be in contact with the right side of the second side surface BS2 and the upper side of the third side surface BS3. The third corner BC3 may be located between the third side surface BS3 and the fourth side surface BS4, and for example, may be in contact with the lower side of the third side surface BS3 and the right side of the fourth side surface BS4. The fourth corner BC4 may be located between the first side surface BS1 and the fourth side surface BS4, and for example, may be in contact with the lower side of the first side surface BS1 and the left side of the fourth side surface BS4.

According to the embodiment, the second side surface AS2, the first corner AC1 and the second corner AC2 included in the first sub-substrate 110a, and the second side surface BS2, the first corner BC1 and the second corner BC2 included in the second sub-substrate 110b may face the bending area BA. The side surfaces AS and BS and the corners AC and BC according to the embodiment may be located toward the outside of the display device 10, except for the second side surface AS2 included in the first sub-substrate 110a and the second side surface BS2 included in the second sub-substrate 110b.

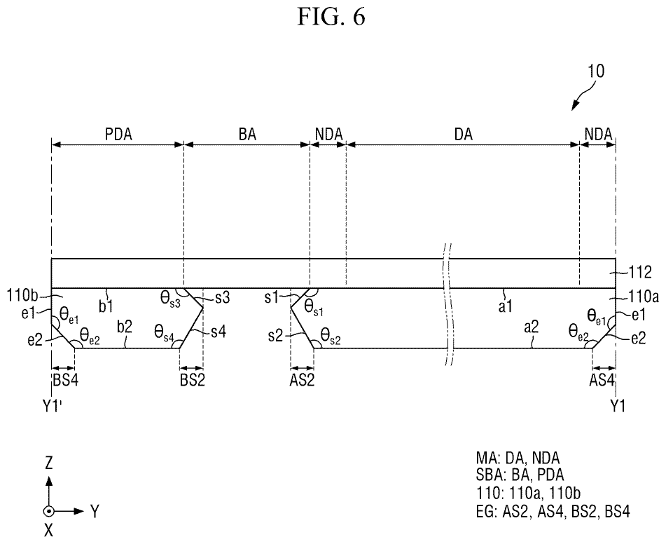

FIG. 6 is a schematic cross-sectional view taken along line Y1-Y1′ of FIG. 5.

Referring to FIG. 6, the first sub-substrate 110a according to the embodiment may include a first surface a1, a second surface a2, a first side surface s1, and a second side surface s2. The first surface a1 of the first sub-substrate 110a may be in contact with the second substrate 112, the second surface a2 may be opposed to the first surface a1, and the first surface a1 and the second surface a2 may be connected with each other by the first side surface s1 and the second side surface s2.

In cross-section, the first side surface s1 and the second side surface s2 of the first sub-substrate 110a may be located such that they overlap the second side surface AS2 included in the edge portions EG.

In an embodiment, the first side surface s1 and the second side surface s2 may be inclined surfaces. For example, the first side surface s1 and the second substrate 112 may form an undercut toward the bending area BA, and the first inclination angle θₛ₁ formed by the first surface a1 and the first side surface s1 may be an obtuse angle. A second inclination angle θₛ₂ formed by the second surface a2 and the second side surface s2 of the first sub-substrate 110a may be an obtuse angle. According to the embodiment, the first side surface s1 and the second side surface s2 may be formed by removing a portion of the first substrate 110 in the bending area BA via an etching process during the process of fabricating the display device 10. The fabrication process will be described later.

In cross-section, the first sub-substrate 110a according to the embodiment may include a first edge surface e1 and a second edge surface e2 overlapping the fourth side surface AS4 included in the edge portions EG. The first edge surface e1 may be connected to the first surface a1 of the first sub-substrate 110a, and the second edge surface e2 may be connected to the second surface a2 of the first sub-substrate 110a. The first surface a1 and the second surface a2 of the first sub-substrate 110a may be connected by the first edge surface e1 and the second edge surface c2.

The second edge surface e2 according to the embodiment may be an inclined surface. As an example, the first inclination angle θₑ₁ formed by the first edge surface e1 and the second edge surface e2, and the second inclination angle θₑ₂ formed by the second edge surface e2 and the second surface a2 may be obtuse angles. The first edge surface e1 and the second edge surface e2 may be formed by removing a portion of the first substrate 110 overlapping the edge portions EG during the process of fabricating the display device 10. The fabrication process will be described later.

In an embodiment, the second sub-substrate 110b may include a first surface b1, a second surface b2, a first side surface s3, and a second side surface s4. The first surface b1 of the second sub-substrate 110b may be in contact with the second substrate 112, the second surface b2 of the second sub-substrate 110b may be opposed to the first surface b1, and the first surface b1 and the second surface b2 may be connected with each other by the first side surface s3 and the second side surface s4. According to the embodiment, the first side surface s1 and the second side surface s2 included in the first sub-substrate 110a may face the first side surface s3 and the second side surface s4 included in the second sub-substrate 110b with the bending area BA therebetween.

In cross-section, the first side surface s3 and the second side surface s4 of the second sub-substrate 110b may be located such that they overlap the second side surface BS2 included in the edge portions EG.

In an embodiment, the first side surface s3 and the second side surface s4 may be inclined surfaces. For example, the first side surface s3 and the second substrate 112 may form an undercut toward the bending area BA, and the first inclination angle θₛ₃ formed by the first surface b1 and the first side surface s3 of the second sub-substrate 110b may be an obtuse angle. A second inclination angle θₛ₄ formed by the second surface b2 and the second side surface s4 of the second sub-substrate 110b may be an obtuse angle.

According to the embodiment, the first side surface s1 and the second side surface s2 of the first sub-substrate 110a located overlapping the second side surface AS2, and the first side surface s3 and the second side surface s4 of the second sub-substrate 110b located overlapping the second side surface BS2 may be results formed by performing the same etching process in the process of fabricating the display device 10. As a result, the first side surface s1 and the second side surface s2 of the first sub-substrate 110a and the first side surface s3 and second side surface s4 of the second sub-substrate 110b have the same shape. The fabrication process will be described later.

The second sub-substrate 110b according to the embodiment may include the first edge surface e1 and the second edge surface e2 overlapping the fourth side surface BS4 included in the edge portions EG. The first edge surface e1 may be connected to the first surface b1 of the second sub-substrate 110b, and the second edge surface e2 may be connected to the second surface b2 of the second sub-substrate 110b. The first surface b1 and the second surface b2 of the second sub-substrate 110b may be connected by the first edge surface e1 and the second edge surface e2.

According to the embodiment, the first edge surface e1 and the second edge surface e2 of the first sub-substrate 110a overlapping the fourth side surface AS4, and the first edge surface e1 and the second edge surface e2 of the second sub-substrate 110b overlapping the fourth side surface BS4 may be results of the same etching process during the process of fabricating the display device 10. Therefore, the first edge surface e1 and the second edge surface e2 of the first sub-substrate 110a and the first edge surface e1 and second edge surface e2 of the second sub-substrate 110b have the same shape. The fabrication process will be described later.

For convenience of illustration, the structures and features of the first substrate 110 and the second substrate 112 overlapping the fourth side surfaces AS4 and BS4 included in the edge portions EG are shown and described. It should be understood, however, that the structures of the first substrate 110 and the second substrate 112 overlapping the first side surfaces AS1 and BS1 and third side surfaces AS3 and BS3 may be identical to the structures of the first substrate 110 and the second substrate 112 overlapping the fourth side surfaces AS4 and BS4 described above. The redundant descriptions will be omitted.

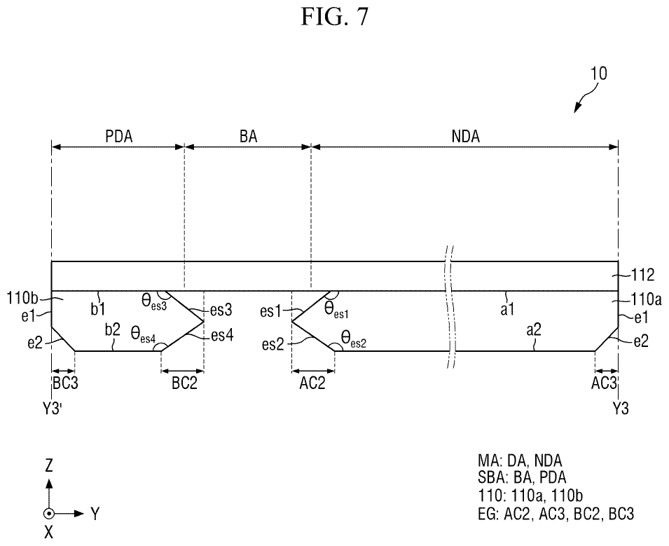

FIG. 7 is a schematic cross-sectional view taken along line Y3-Y3′ of FIG. 5.

Referring to FIG. 7, the first sub-substrate 110a according to the embodiment may include a first surface a1, a second surface a2, a first edge surface e1, and a second edge surface e2, as well as a first side surface es1 and a second side surface es2. In cross-section, the first edge surface e1 and the second edge surface e2 of the first sub-substrate 110a may be located such that they overlap the third corner AC3 included in the edge portions EG. The first edge surface e1 and the second edge surface e2 of the first sub-substrate 110a may be located such that they overlap the third corner AC3 included in the edge portions EG. The first edge surface e1 and the second edge surface e2 overlapping of the third corner AC3 may have the same structure and features with the first edge surface e1 and the second edge surface e2 overlapping the fourth side surface AS4 described above with reference to FIG. 6. The redundant descriptions will be omitted.

According to the embodiment, the first side surface es1 and the second side surface es2 included the first sub-substrate 110a may be located such that they overlap the second side surface AS2 included in the edge portions EG. The second corner AC2 may overlap the bending area BA or may be adjacent to the bending area BA.

In an embodiment, the first side surface es1 and the second side surface es2 may be inclined surfaces. For example, the first side surface es1 and the second substrate 112 may form an undercut toward the bending area BA, and the first inclination angle θₑₛ₁ formed by the first surface a1 and the first side surface es1 may be an obtuse angle. A second inclination angle θₑₛ₂ formed by the second surface a2 and the second side surface es2 of the first sub-substrate 110a may be an obtuse angle.

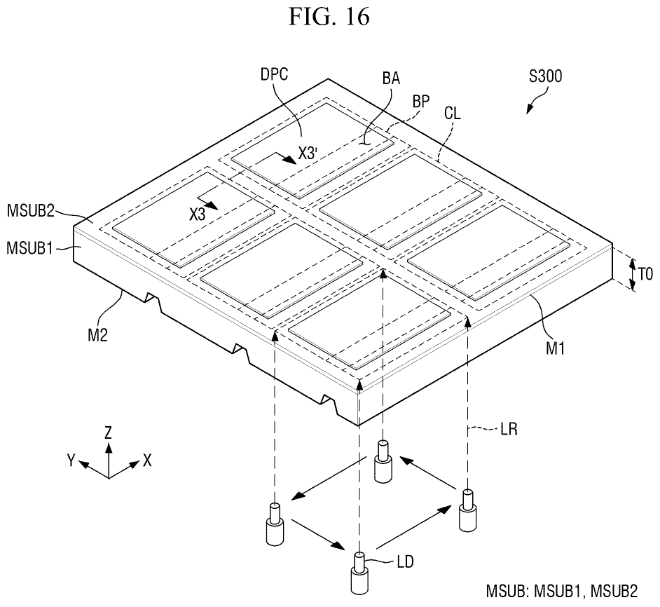

According to the embodiment, the first side surface es1 and the second side surface es2 may be formed by removing a portion of the first substrate 110 in the bending area BA via an etching process during the process of fabricating the display device 10. At the same time, according to the embodiment, the first side surface es1 and the second side surface es2 may be formed by removing a portion of the first substrate 110 in line with a cell-cut line (the line CL of FIG. 16) to be described later via an etching process during the process of fabricating the display device 10. The fabrication process will be described later.

According to the embodiment, the second sub-substrate 110b may include a first side surface es3 and a second side surface es4 in addition to the first surface b1, the second surface b2, the first edge surface e1 and the second edge surface e2. The first edge surface e1 and the second edge surface e2 of the second sub-substrate 110a may be located such that they overlap the third corner BC3 included in the edge portions EG. The first edge surface e1 and the second edge surface e2 overlapping of the third corner BC3 may have the same structure and features with the first edge surface e1 and the second edge surface e2 overlapping the fourth side surface BS4 described above with reference to FIG. 6. The redundant descriptions will be omitted.

In cross-section, according to the embodiment, the first side surface es3 and the second side surface es4 of the second sub-substrate 110b may be located such that they overlap the second corner BC2 included in the edge portions EG. The second corner BC2 may overlap the bending area BA or may be adjacent to the bending area BA.

In an embodiment, the first side surface es3 and the second side surface es4 may be inclined surfaces. For example, the first side surface es1 and the second substrate 112 may form an undercut toward the bending area BA, and the first inclination angle θₑₛ₃ formed by the first surface b1 and the first side surface es3 may be an obtuse angle. A second inclination angle θₑₛ₄ formed by the second surface b2 and the second side surface es4 of the second sub-substrate 110b may be an obtuse angle. According to the embodiment, the first side surface es1 and the second side surface es2 included in the first sub-substrate 110a may face the first side surface es3 and the second side surface es4 included in the second sub-substrate 110b with the bending area BA therebetween.

According to the embodiment, the first side surface es1 and the second side surface es2 of the first sub-substrate 110a overlapping the second corner AC2, and the first side surface es3 and the second side surface es4 of the second sub-substrate 110b overlapping the second corner BC2 may be results of the same etching process during the process of fabricating the display device 10. As a result, the first side surface es1 and the second side surface es2 of the first sub-substrate 110a and the first side surface es3 and second side surface es4 of the second sub-substrate 110b have the same shape. For example, the first side surface es3 and the second side surface es4 included in the second sub-substrate 110b may be formed by removing a portion of the first substrate 110 in the bending area BA via an etching process and simultaneously removing a portion of the first substrate 110 in line with the cell-cut line (the line CL of FIG. 16) to be described later via an etching process during the process of fabricating the display device 10. The fabrication process will be described later.

For convenience of illustration, the structures and features of the first substrate 110 and the second substrate 112 overlapping the second corners AC2 and BC2 and the third corners AC3 and BC3 included in the edge portions EG are shown and described. It should be understood, however, that the structures of the first substrate 110 and the second substrate 112 overlapping the first corners AC1 and BC1 may be identical to the structures of the first substrate 110 and the second substrate 112 overlapping the second corners AC2 and BC3 described above. The structures of the first substrate 110 and the second substrate 112 overlapping the fourth corners AC4 and BC4 according to the embodiment may be identical to the structures of the first substrate 110 and the second substrate 112 overlapping the third corners AC3 and BC3 described above. The redundant descriptions will be omitted.

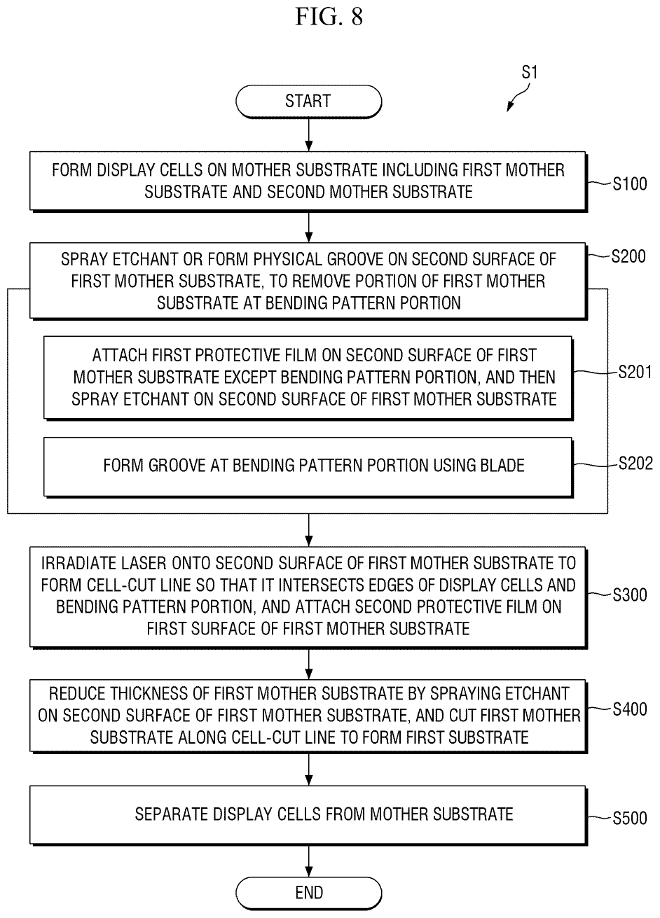

Hereinafter, a method of fabricating a display device according to an embodiment will be described with reference to FIGS. 8 to 23. FIG. 8 is a flowchart for illustrating a method of fabricating a display device 10 according to an embodiment.

Referring to FIG. 8, a method S1 of fabricating a display device according to an embodiment may include: forming a display cell on a mother substrate including a first mother substrate and a second mother substrate (step S100); removing a portion of the first mother substrate at a bending pattern portion by spraying an etchant or forming a physical groove on a second surface of the first mother substrate (step S200); irradiating a laser onto the second surface of the first mother substrate to form a cell-cut line so that it intersects an edge of the display cell as well as the bending pattern portion, and attaching a second protective film on a first surface of the first mother substrate (step S300); spraying an etchant on the second surface of the first mother substrate to reduce the thickness of the first mother substrate and simultaneously cutting the first mother substrate along the cell-cut line to form a first substrate (step S400); and separating display cells from the mother substrate (step S500). As shown in FIG. 8, The removing S200 a portion of the first mother substrate at the bending pattern portion by spraying an etchant or forming a physical groove on the second surface of the first mother substrate may be carried out by selecting one of two following methods: The first method is to attach a first protective film on the second surface of the first mother substrate, except the bending pattern portion, and spray an etchant onto the second surface of the first mother substrate (step S201). The second method is to form a groove using a blade at the bending pattern portion (step S202).

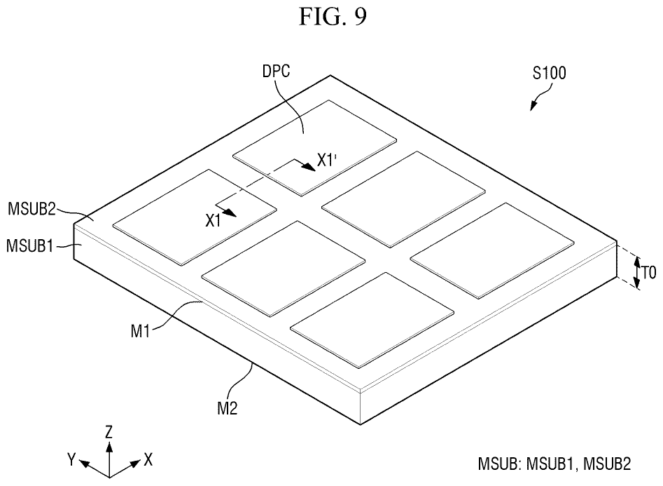

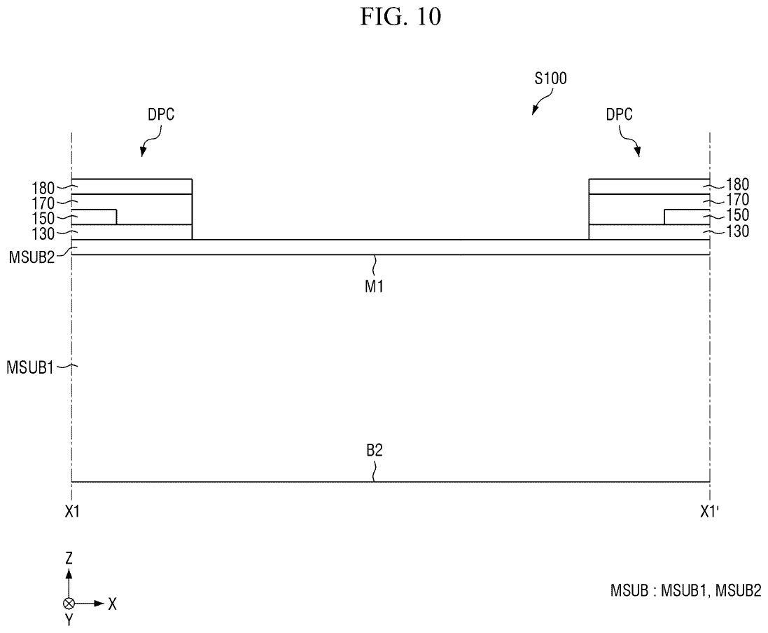

FIG. 9 is a schematic perspective view for illustrating step S100 of FIG. 8. FIG. 10 is a schematic cross-sectional view taken along line X1-X1′in FIG. 9.

Referring to FIGS. 9 and 10 in conjunction with FIG. 8, the method may include forming display cells DPC on a mother substrate MSUB including a first mother substrate MSUB1 and a second mother substrate MSUB2 (step S100 of FIG. 8).

The mother substrate MSUB according to the embodiment may include the first mother substrate MSUB1 and the second mother substrate MSUB2, and the second mother substrate MSUB2 may be disposed on the first mother substrate MSUB1. The first mother substrate MSUB1 may be made of a rigid material, while the second mother substrate MSUB2 may be made of a flexible material. In this process, the thickness T0 of the first mother substrate MSUB may be, but is not limited to, about 500 μm.

Subsequently, display cells DPC may be formed on the mother substrate MSUB. The display cells DPC may be arranged such that they are spaced apart from one another in the first direction (x-axis direction) and the second direction (y-axis direction) in plan view.

In cross-section, each of the display cells DPC may include the first mother substrate MSUB1, the second mother substrate MSUB2 disposed on an upper surface M1 of the first mother substrate MSUB1, the thin-film transistor layer 130 disposed on the second mother substrate MSUB2, the display element layer 150 disposed on the thin-film transistor layer 130, the thin-film encapsulation layer 170 disposed on the display element layer 150 and the touch sensor layer 180 disposed on the thin-film encapsulation layer 170.

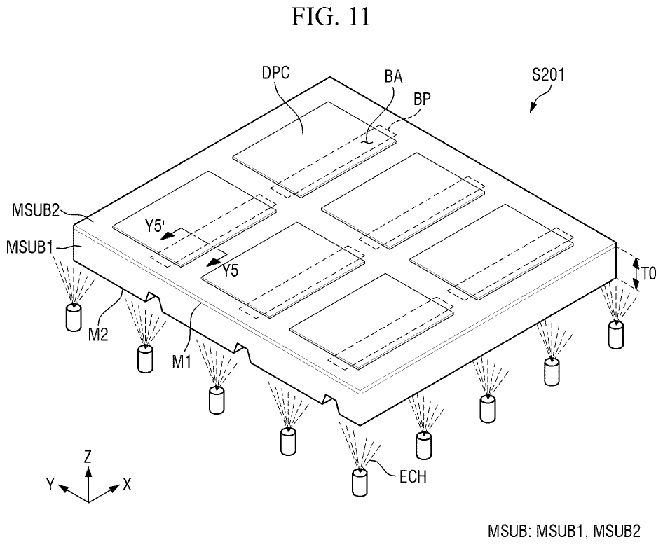

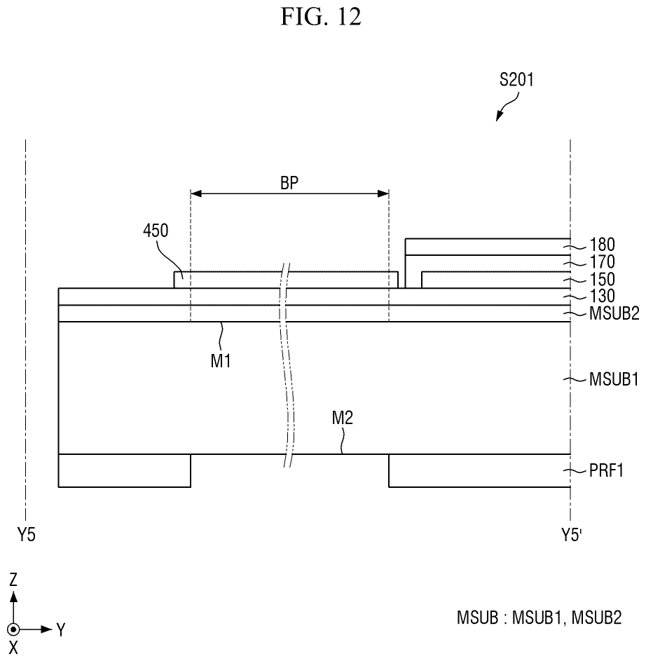

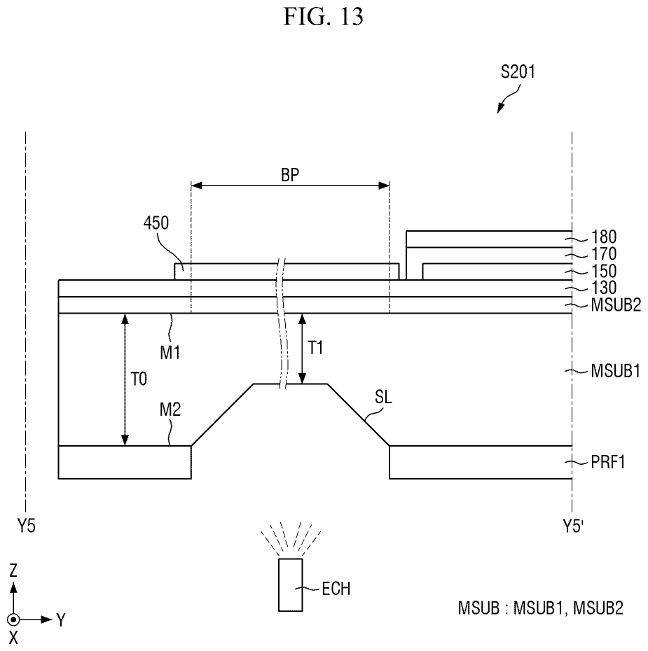

FIG. 11 is a schematic perspective view showing step S201 of step S200 in FIG. 8. FIGS. 12 and 13 are schematic cross-sectional views taken along line Y5-Y5′ of FIG. 11.

Referring to FIGS. 11 and 13 in conjunction with FIG. 8, as the removing S200 a portion of the first mother substrate MSUB1 at the bending pattern portion BP by spraying an etchant or forming a groove on a lower surface M2 of the first mother substrate MSUB1, the method S201 to attach a first protective film PRF1 on the lower surface M2 of the first mother substrate MSUB1, except the bending pattern portion BP and spray an etchant onto the lower surface M2 of the first mother substrate MSUB1 is carried out.

Initially, the first protective film PRF1 may be attached to the lower surface M2 of the first mother substrate MSUB1. The first protective film PRF1 may be attached to a part of the lower surface M2 of the first mother substrate MSUB1 excluding the bending pattern portion BP.

The first protective film PRF1 may be an acid-resistant film. The first protective film PRF1 can prevent the first mother substrate MSUB1 from being etched where the first protective film PRF1 is attached.

In this process, the bending pattern portion BP may be an area that overlaps the bending area BA so that a portion of the first mother substrate MSUB1 can be etched. The bending pattern portion BP may be in line with the bending protection layer 450. The lower surface M2 of the first mother substrate MSUB1 in line with the bending pattern portion BP may be exposed.

Subsequently, a portion of the first mother substrate MSUB1 may be etched by spraying an etchant ECH onto the lower surface M2 of the first mother substrate MSUB1. As an example, the etching process of this process may be performed as an anisotropic wet etching process.

In this process, the thickness T1 of the first mother substrate MSUB1 in the bending pattern portion BP may be smaller than the thickness T0 of the first mother substrate MSUB1 except the bending pattern portion BP. After the first mother substrate MSUB1 has been etched, the first mother substrate MSUB1 may include inclined surfaces SL in the bending pattern portion BP.

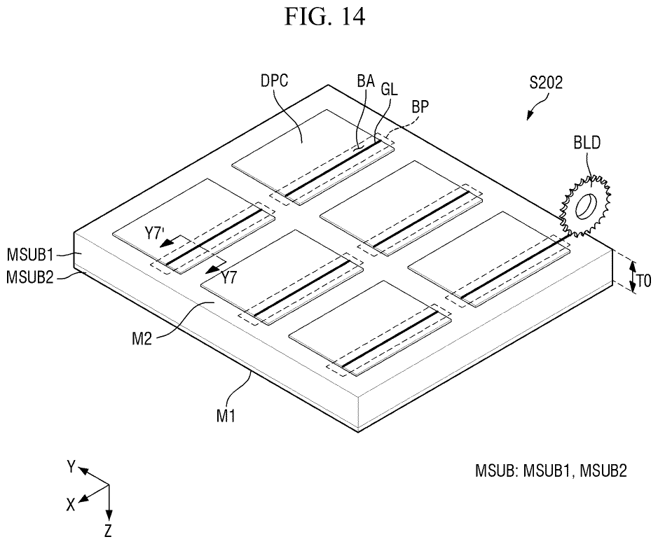

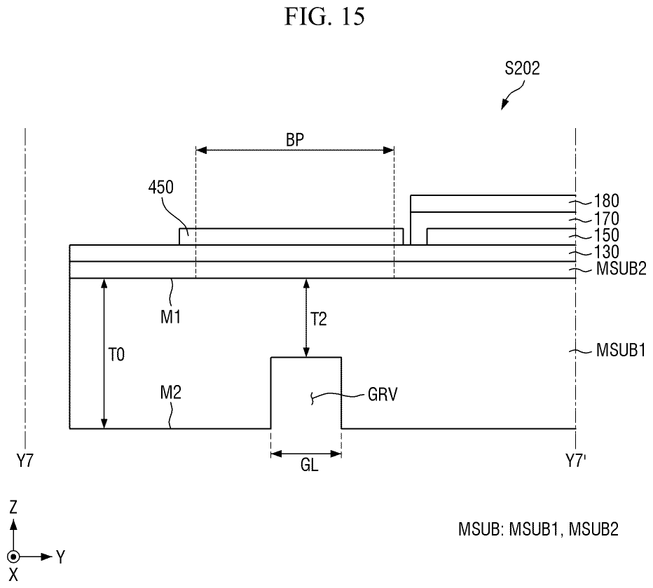

FIG. 14 is a schematic perspective view showing step S202 of step S200 in FIG. 8. FIG. 15 is a schematic cross-sectional view taken along line Y7-Y7′ of FIG. 14.

Referring to FIGS. 14 and 15 in conjunction with FIG. 8, as the removing S200 a portion of the first mother substrate MSUB1 at the bending pattern portion BP by spraying an etchant or forming a groove on the lower surface M2 of the first mother substrate MSUB1, the method S202 to form a groove GRV using a blade BLD at the bending pattern portion is carried out.

Initially, a groove line GL is formed on the lower surface M2 of the first mother substrate MSUB1 in the bending pattern portion BP. The groove line GL may be a guide line that assists in physically forming the groove GRV on the lower surface M2 of the first mother substrate MSUB1 using a blade BLD. The blade BLD may move in the first direction (x-axis direction) from one side or a side of the first mother substrate MSUB1 to the opposite side of the first mother substrate MSUB1 along the groove line GL.

In cross-section, the thickness T2 of the first mother substrate MSUB1 at the groove GRV may be smaller than the thickness T0 of the first mother substrate MSUB1 except the bending pattern portion BP. Although the cross-sectional shape of the groove GRV is a rectangle in the drawings, it is not limited thereto. For example, the cross-sectional shape of the groove GRV may be a polygon such as a triangle and a trapezoid, or may include a curved line such as a U-shape.

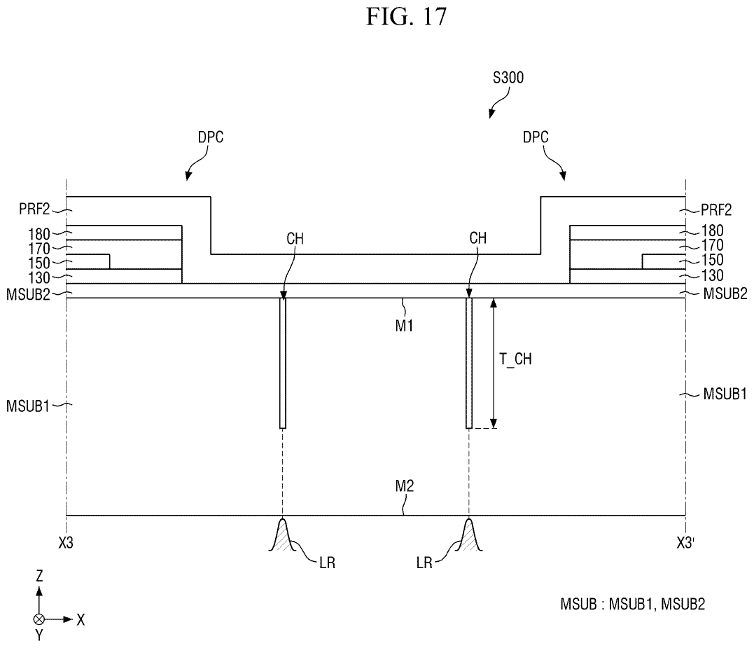

FIG. 16 is a schematic perspective view for illustrating step S300 of FIG. 8. FIG. 17 is a schematic cross-sectional view, taken along line X3-X3′ in FIG. 16.

Referring to FIGS. 16 and 17 in conjunction with FIG. 8, the method may include irradiating laser onto the lower surface M2 of the first mother substrate MSUB1 to form a cell-cut line CL so that the edges of the display cells DPC and the bending pattern portion BP intersect each other, and attaching a second protective film PRF2 on the upper surface M1 of the first mother substrate MSUB1 (step S300).

Initially, laser LR is irradiated onto the lower surface M2 of the first mother substrate MSUB1 to form a cell-cut line CL surrounding the display cells DPC. It should be understood, however, that the embodiments are not limited thereto. The laser LR may be irradiated onto the upper surface M1 of the first mother substrate MSUB1. A part of the first substrate 110 in line with the cell-cut line CL in plan view may form laser irradiation regions CH in cross-section. In other words, the cell-cut line CL may be formed in plan view by connecting the laser irradiation regions CH located in cross-section.

The laser LR may be emitted from the laser device LD. A variety of lasers may be used as the laser LR according to the embodiment. For example, the laser LR according to the embodiment may be, but is not limited to, an infrared Bessel beam with a wavelength of about 1030 nm. In case that the laser LR is irradiated onto the lower surface M2 of the first mother substrate MSUB1, the depth T_CH of each of the laser irradiation regions CH may be adjusted according to the repetition rate, processing speed, and pulse energy.

In an embodiment, the depth T_CH of each of the laser irradiation regions CH may be smaller than the thickness of the first mother substrate MSUB1. For example, in case that the thickness of the first mother substrate MSUB1 is about 500 μm, the depth T_CH of each of the laser irradiation regions CH may be in a range of about 50 μm to about 300 μm. It should be understood, however, that the embodiments are not limited thereto. The depth T_CH of each of the laser irradiation regions CH may be equal to the thickness of the first mother substrate MSUB1.

Subsequently, the second protective film PRF2 may be attached on the display cells DPC. The second protective film PRF2 may cover the display cells DPC altogether. The second protective film PRF2 may cover the display cells DPC and the second mother substrate MSUB2. The second protective film PRF2 may be an acid-resistant film. The second protective film PRF2 can protect the display cells DPC from an etchant in a process of etching the first mother substrate MSUB1.

According to the embodiment, the cell-cut line CL may surround the border of the display cells DPC and intersect the bending pattern portion BP in plan view. In the display device 10 according to the embodiment, the cell-cut line CL is formed to intersect the bending pattern portion BP during the fabrication process, so that the thickness of the first mother substrate MSUB1 can be reduced in a subsequent etching process, and the display cells DPC can be separated from the first mother substrate MSUB. For example, as the cell-cut line CL intersects the bending pattern portion BP in the display device 10 according to the embodiment, the fabrication process can be unified, thereby providing convenience and case of fabrication. As the cell-cut line CL intersects the bending pattern portion BP in the display device 10 according to the embodiment, the spacing between the display cells DPC adjacent to each other can be minimized, and accordingly the number of the display cells DPC included in the mother substrate MSUB can be increased. In other words, the area efficiency occupied by the display cells DPC can be increased compared to the size of the mother substrate MSUB.

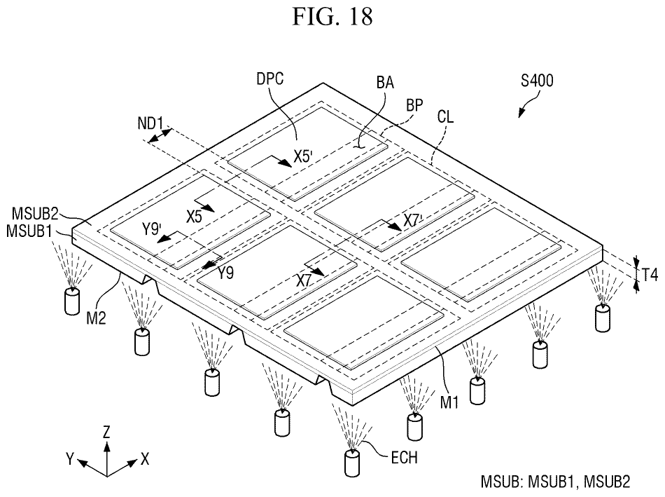

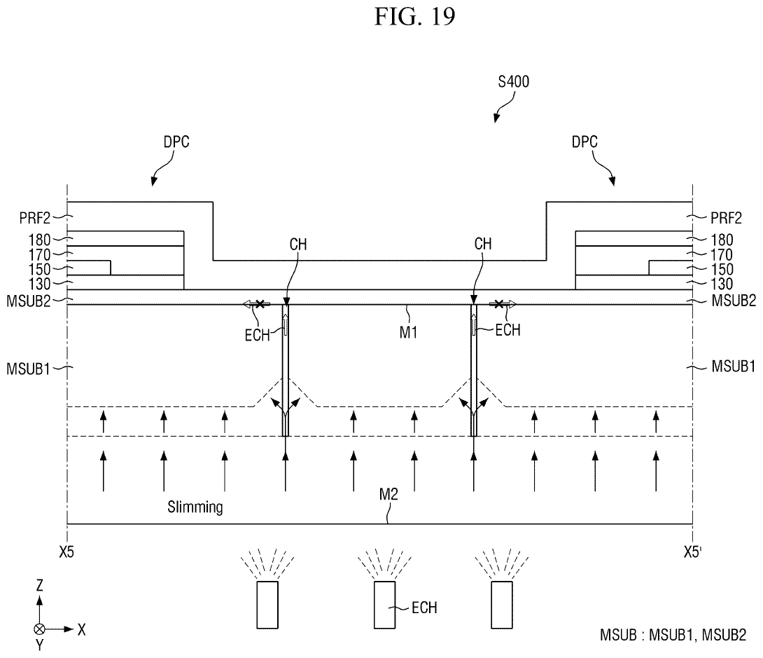

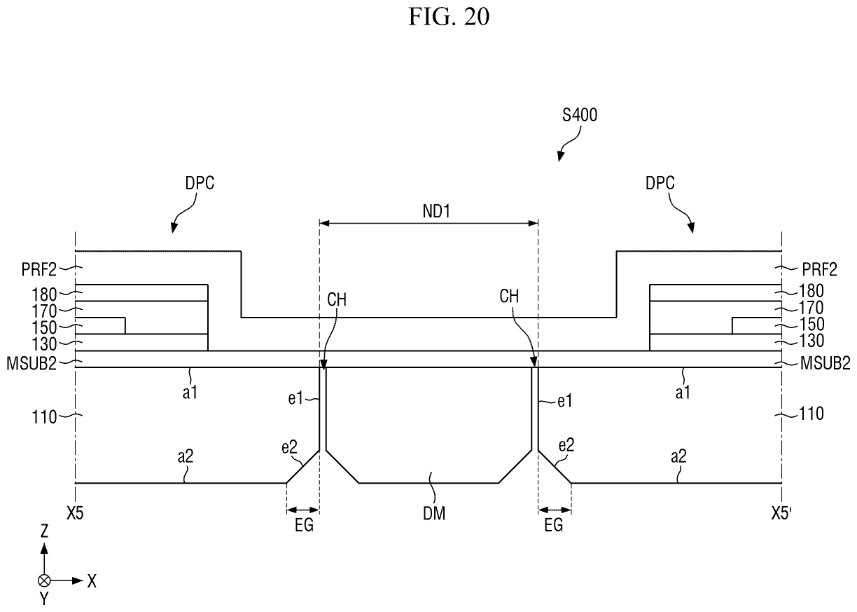

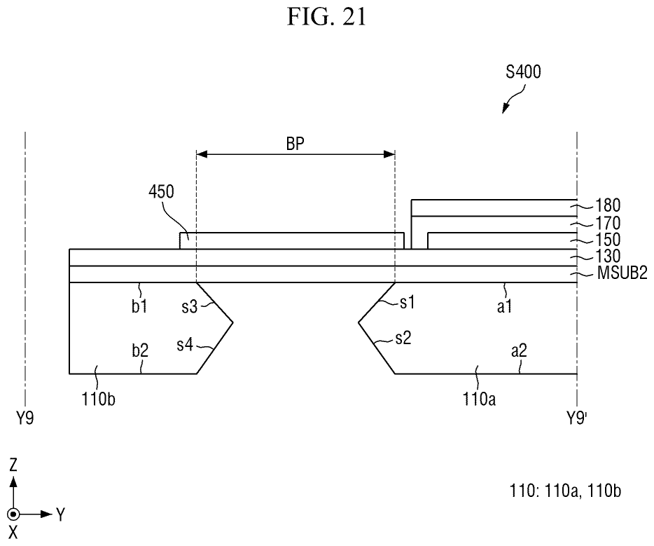

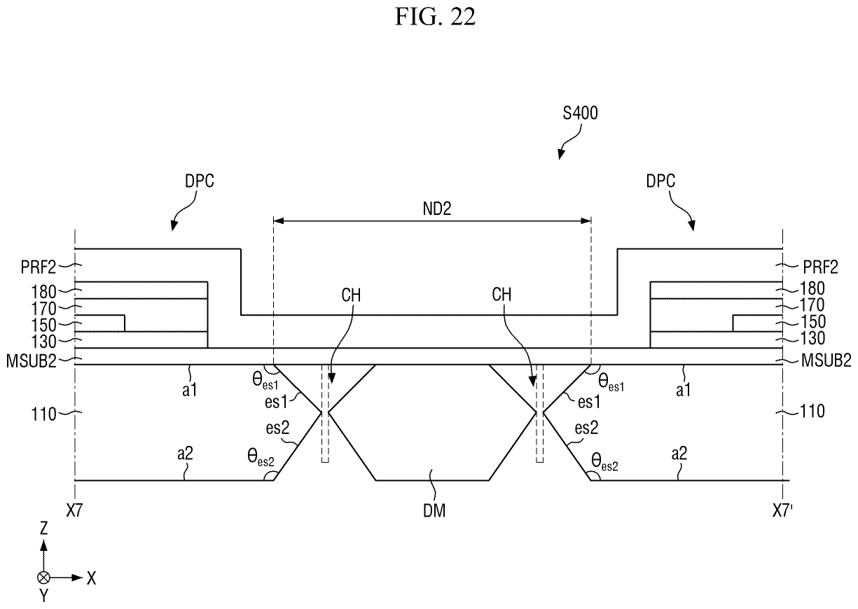

FIG. 18 is a schematic perspective view for illustrating step S400 of FIG. 8. FIGS. 19 and 20 are schematic cross-sectional views, taken along line X5-X5′ of FIG. 18. FIG. 21 is a schematic cross-sectional view, taken along line Y9-Y9′ of FIG. 18. FIG. 22 is a schematic cross-sectional view, taken along line X7-X7′ of FIG. 18.

Referring to FIGS. 18 to 22 in conjunction with FIG. 8, the method may include reducing the thickness of the first mother substrate MSUB1 by spraying an etchant onto the lower surface M2 of the first mother substrate MSUB1, and cutting the first mother substrate MSUB1 along the cell-cut line CL to form the first substrate 110 (step S400). In this process, the thickness T4 of the first mother substrate MSUB may be, but is not limited to, about 200 μm.

Referring to FIG. 19, the entire lower surface M2 of the first mother substrate MSUB1 is etched using an etchant ECH without a separate mask. In cross-section, the physical properties of the laser irradiation regions CH may have been changed by the laser. Therefore, in this process, while the thickness of the first mother substrate MSUB1 is reduced by the etchant ECH, in case that the etchant ECH permeates into the laser irradiation regions CH, there may be a difference in etch rate between the laser irradiation regions CH and the other regions. In other words, the etch rate of the laser irradiated regions CH by the etchant ECH may be higher than the etch rate of other regions of the first mother substrate MSUB1 that are not irradiated with the laser. As a result, the first mother substrate MSUB1 may be anisotropically etched, where the etch rate in the laser irradiation regions CH is faster than the etch rate in the other regions than the laser irradiation regions CH.

Referring to FIG. 20, the first substrate 110 according to the embodiment may include, a first edge surface e1 and a second edge surface e2 at the edge portions EG, in addition to the first surface a1 and the second surface a2. According to the embodiment, the first edge surface e1 and the second edge surface e2 may be positioned at the periphery of the laser irradiation regions CH in cross-section, and may overlap the periphery of the cell-cut line CL in plan view. The second edge surface e2 according to the embodiment may be an inclined surface. The redundant descriptions will be omitted.

The first substrate 110 may be formed in this process. After the first substrate 110 has been separated, a part of the first mother substrate MSUB1 may remain as a dummy DM. As described above, in the display device 10 according to the embodiment, the cell-cut line CL intersects the bending pattern portion BP during the fabrication process, so that a distance NDI between the display cells DPC can be reduced. For example, in the display device 10 according to the embodiment, the area of the dummy DM can be reduced, and thus the display cells DPC can be arranged more efficiently in the mother substrate MSUB.

In this process, the first substrate 110 is separated from the first mother substrate MSUB1 and at the same time, a portion of the first substrate 110 overlapping the bending pattern portion BP may be etched.

Referring to FIG. 21, in this process, the portion of the first substrate 110 overlapping the bending pattern portion BP may be completely removed, such that a first sub-substrate 110a and a second sub-substrate 110b may be formed.

In this process, the first sub-substrate 110a may have a first surface a1, a second surface a2, a first side surface s1, and a second side surface s2, and the second sub-substrate 110b may have a first side surface b1, a second surface b2, a first side surface s3, and a second side surface s4. According to the embodiment, the second mother substrate MSUB and the first side surface s1 may form an undercut toward the bending pattern portion BP, and the first side surface s1 and the second side surface s2 may be inclined surfaces. According to the embodiment, the second mother substrate MSUB and the first side surface s3 may form an undercut toward the bending pattern portion BP, and the first side surface s1 and the second side surface s2 may be inclined surfaces. The redundant descriptions will be omitted.

FIG. 22 shows a cross-sectional structure of the first substrate 110 positioned at the intersection of the bending pattern portion BP and the cell-cut line CL in FIG. 18. The cross-sectional structure of the first substrate 110 at the intersection of the bending pattern portion BP and the cell-cut line CL may have a shape different from that of the first substrate 110 at the periphery of the cell-cut line CL and the first substrate 110 at the bending pattern portion BP. For example, the cross-sectional structure of the first substrate 110 located at the intersection of the bending pattern portion BP and the cell-cut line CL in plan view may have a different shape from the first edge surface e1 and the second edge surface e2 of the first substrate 110 shown in FIG. 20, and the first side surfaces s1 and s3 and the second side surfaces s2 and s4 of the first substrate 110 shown in FIG. 21.

Referring to FIG. 22, the first substrate 110 at the intersection of the bending pattern portion BP and the cell-cut line CL in plan view may include a first side surface es1 and a second side surface es2 toward the laser irradiation regions CH in cross-section. The first side surface es1 and the second side surface es2 may be inclined surfaces, and the second mother substrate MSUB2 and the first side surface es1 may form an undercut toward the outside of the first substrate 110.

According to the embodiment, the first side surface es1 and the second side surface es2 may be formed by simultaneously performing an etching process at the bending pattern portion BP and an etching process in line with the cell-cut line CL. In other words, in the first substrate 110 at the intersection of the bending pattern portion BP and the cell-cut line CL in plan view, an anisotropic etching shape caused by the formation of the laser irradiation regions CH and an anisotropic etching shape caused by the already removed portion of the first substrate 110 at the bending pattern portion BP may be formed simultaneously.

The first inclination angle θₑₛ₁ and the second inclination angle θₑₛ₂ according to the embodiment may vary depending on process factors in forming the cell-cut line CL and process factors in forming the bending pattern portion BP. The spacing ND2 between the display cells DPC may also vary depending on process factors in forming the cell-cut line CL and process factors in forming the bending pattern portion BP. For example, the first inclination angle θₑₛ₁, the second inclination angle θₑₛ₂, and the spacing ND2 between the display cells DPC may vary depending on the location of the laser irradiation regions CH, the intensity, type and size of the laser, as well as the type of etchant, the etchant exposure time, groove depth, type of groove, etc. Subsequently, the second protective film PRF2 is removed, and the second mother substrate MSUB2 is cut along the cell-cut line CL.

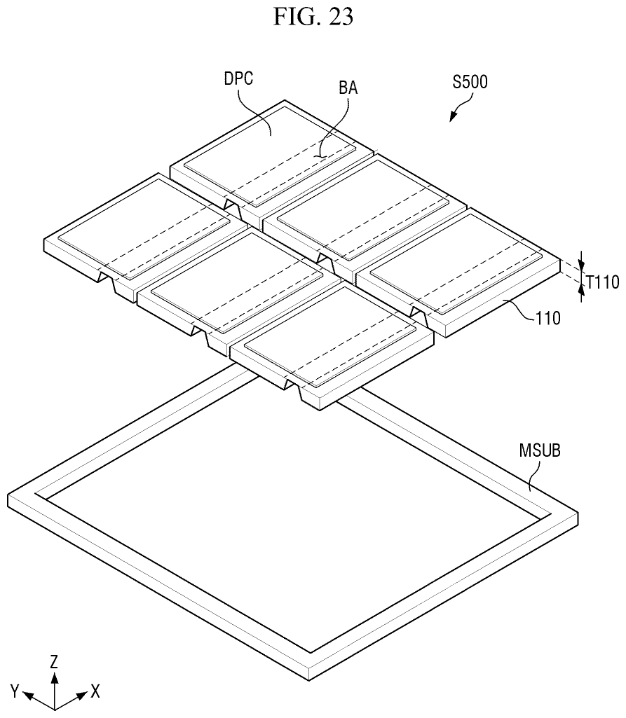

Subsequently, referring to FIG. 23, the method may include separating the display cells DPC from the mother substrate MSUB (step S500 of FIG. 8). In this process, the thickness T110 of the first substrate 110 may be about 200 μm, and each of the display cells DPC may have the shape of the display device 10 shown in FIG. 3.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a first substrate comprising a main area and a pad area; and
a second substrate disposed on the main area and the pad area of the first substrate, the second substrate comprising a bending area disposed between the main area and the pad area, wherein
the first substrate comprises:
a first sub-substrate in line with the main area; and
a second sub-substrate in line with the pad area and spaced apart from the first sub-substrate with the bending area between the first sub-substrate and the second sub-substrate,
the first sub-substrate comprises an edge portion at an edge surrounding the first sub-substrate in plan view,
the edge portion of the first sub-substrate comprises:
a first side surface facing the bending area,
a second side surface spaced apart from the first side surface, and
a first corner disposed between the first side surface and the second side surface, and
the first sub-substrate has different cross-sectional shapes at the first side surface, the second side surface and the first corner in cross-section.

2. The display device of claim 1, wherein
the first sub-substrate comprises a first surface facing the second substrate and a second surface opposed to the first surface,
the first sub-substrate further comprises a first side surface connected to the first surface at the first corner, and
a first inclination angle formed by the first surface and the first side surface is an obtuse angle.

3. The display device of claim 2, wherein an undercut is formed between the first side surface and the second substrate toward an outside of the first sub-substrate.

4. The display device of claim 2, wherein
the first sub-substrate further comprises a second side surface connecting the second surface and the first surface at the first corner, and
a second inclination angle formed by the second surface and the second side surface is an obtuse angle.

5. The display device of claim 4, wherein
the first sub-substrate further comprises:
a first bending side surface connected to the first surface at the first side surface, and
a second bending side surface connecting the first bending side surface with the second surface,
a first bending inclination angle formed by the first surface and the first bending side surface is an obtuse angle, and
the first bending inclination angle and the first inclination angle are different from each other.

6. The display device of claim 5, wherein
a second bending inclination angle formed by the second surface and the second bending side surface at the first side surface is an obtuse angle, and
the second inclination angle and the second bending inclination angle are different from each other.

7. The display device of claim 4, wherein
the first sub-substrate further comprises a first edge surface connected to the first surface at the second side surface and a second edge surface connecting the first edge surface with the second surface, and
no undercut is included between the second substrate and the first edge surface at the second side surface.

8. The display device of claim 7, wherein a first edge inclination angle formed by the first edge surface and the second edge surface is an obtuse angle.

9. The display device of claim 7, wherein
a second edge inclination angle formed by the second surface and the second edge surface at the second side surface is an obtuse angle, and
the second inclination angle and the second edge inclination angle are different from each other.

10. The display device of claim 1, wherein a thickness of the first substrate is greater than a thickness of the second substrate.

11. The display device of claim 10, wherein the thickness of the first substrate is equal to about 200 μm.

12. The display device of claim 1, wherein
the second sub-substrate comprises an edge portion at an edge surrounding the second sub-substrate in plan view,
the edge portion of the second sub-substrate comprises:
a third side surface facing the bending area,
a fourth side surface spaced apart from the first side surface, and
a second corner disposed between the third side surface and the fourth side surface, and
the second sub-substrate has different cross-sectional shapes at the third side surface, the fourth side surface and the second corner in cross-section.

13. The display device of claim 12, wherein
the second sub-substrate comprises:
a first surface facing the second substrate, and
a second surface opposed to the first surface,
the second sub-substrate further comprises a first side surface connected to the first surface at the second corner, and a second side surface connecting the second surface with the first side surface, and
a first inclination angle formed by the first surface and the first side surface and a second inclination angle formed by the second surface and the second side surface are obtuse angles.

14. The display device of claim 13, wherein an undercut is formed between the first side surface and the second substrate toward an outside of the second sub-substrate.

15. The display device of claim 14, wherein
the second sub-substrate further comprises:
a first edge surface connected to the first surface at the fourth side surface, and
a second edge surface connecting the first edge surface with the second surface, and
no undercut is included between the second substrate and the first edge surface at the fourth side surface.

16. The display device of claim 13, wherein
the second sub-substrate further comprises:
a first bending side surface connected to the first surface at the third side surface, and
a second bending side surface connecting the first bending side surface with the second surface,
a first bending inclination angle formed by the first surface and the first bending side surface and a second bending inclination angle formed by the second surface and the second bending side surface are obtuse angles,
the first bending inclination angle and the first inclination angle are different from each other, and
the second bending inclination angle and the second inclination angle are different from each other.

17. A method of fabricating a display device, the method comprising:
forming a mother substrate comprising a first mother substrate and a second mother substrate disposed on a first surface of the first mother substrate, and forming a plurality of display cells on the mother substrate;
etching a portion of the first mother substrate disposed at a bending pattern portion by spraying an etchant or forming a groove using a blade on a second surface of the first mother substrate disposed on an opposite side of the first surface;
forming a cell-cut line along edges of the plurality of display cells by irradiating a laser on the second surface; and
forming a first substrate by spraying an etchant on the second surface without a mask to cut the first mother substrate and simultaneously removing the first mother substrate at the bending pattern portion,
wherein a part of the cell-cut line intersects the bending pattern portion.

18. The method of claim 17, wherein
the first mother substrate at an intersection of the cell-cut line and the bending pattern portion has a first side surface and a second side surface connected to the first side surface toward the cell-cut line and the bending pattern portion,
the first side surface is connected to the first surface of the first mother substrate, and the second side surface is connected to the second surface of the first mother substrate, and
an undercut is formed between the first side surface and the second mother substrate toward an outside of the first substrate.

19. The display device of claim 18, wherein a first inclination angle formed by the first surface of the first mother substrate and the first side surface is an obtuse angle.

20. The display device of claim 19, wherein a second inclination angle formed by the second surface of the first mother substrate and the first side surface is an obtuse angle.

21. An electronic device comprising:
a display device comprising a first substrate comprising a main area and a pad area; and
a second substrate disposed on the main area and the pad area of the first substrate, the second substrate comprising a bending area disposed between the main area and the pad area, wherein
the first substrate comprises:
a first sub-substrate in line with the main area; and
a second sub-substrate in line with the pad area and spaced apart from the first sub-substrate with the bending area between the first sub-substrate and the second sub-substrate,
the first sub-substrate comprises an edge portion at an edge surrounding the first sub-substrate in plan view,
the edge portion of the first sub-substrate comprises:
a first side surface facing the bending area,
a second side surface spaced apart from the first side surface, and
a first corner disposed between the first side surface and the second side surface, and
the first sub-substrate has different cross-sectional shapes at the first side surface, the second side surface and the first corner in cross-section.
